(19) United States
(12) Patent Application Publication
(10) Pub. No.: US 2019/0235677 A1
(43) Pub. Date: Aug. 1, 2019

(54) MICRO LED TOUCH PANEL DISPLAY

(71) Applicant: HON HAI PRECISION INDUSTRY CO., LTD., New Taipei (TW)

(72) Inventors: CHIA-LIN LIU, New Taipei (TW); YU-FU WENG, New Taipei (TW); CHIEN-WEN LIN, New Taipei (TW); TZU-YU CHENG, New Taipei (TW)

(21) Appl. No.: 16/123,064

(22) Filed: Sep. 6, 2018

(30) Foreign Application Priority Data
Feb. 1, 2018 (CN) 201810103621.0

(51) Int. Cl. G06F 3/041; H01L 31/173; H01L 31/02; G06F 3/042; G09G 3/32

(52) U.S. Cl. CPC G06F 3/0412; H01L 31/173; H01L 31/02019; G09G 2354/00; G09G 3/32; G06F 3/0416; G09G 2360/145; G06F 3/0421

(57) ABSTRACT

A micro LED touch panel display includes the functions of a touch screen and micro LEDs. The touch panel display further includes a plurality of photodiodes. The photodiodes are configured to detect positions of touches by sensing variations of light intensity when a fingertip is pressed against the panel. The disclosure integrates touch technology into the micro LED touch panel display.

### FIELD

The subject matter herein generally relates to touch panel displays.

### BACKGROUND

Micro-LED (Micro Light Emitting Diode), also known as micro LEDs or μLEDs, is an emerging flat panel display technology. Currently, a micro LED display panel generally includes an N-type doped inorganic light-emitting material layer, a P-type doped inorganic light-emitting material layer, a transparent conductive layer electrically connected to the N-type doped inorganic light-emitting material layer (as a cathode), and a metal layer electrically connected to the P-type doped inorganic light-emitting material layer (as an anode). However, conventional micro LED display panels do not incorporate touch technology.

Therefore, there is room for improvement in the art.

### BRIEF DESCRIPTION OF THE DRAWINGS

Implementations of the present disclosure will now be described, by way of example only, with reference to the attached figures.

FIG. 1A is a cross-sectional view of an embodiment of a micro LED touch panel display.

FIG. 1B is a cross-sectional view of the micro LED touch panel display of FIG. 1 with a fingertip touching the panel.

FIG. 2 is a planar view showing a layout of a plurality of pixel units according to a first embodiment of the micro LED touch panel display.

FIG. 3 is a planar view showing a layout of a plurality of pixel units according to another embodiment of the micro LED touch panel display.

FIG. 4 is a circuit diagram of the first embodiment of a touch unit.

FIG. 5 is a circuit diagram of another embodiment of the touch unit.

FIG. 6 is a cross-sectional view of the first embodiment of a micro LED.

FIG. 7 is a cross-sectional view of a first embodiment of a photodiode.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the common, identical embodiment, and such references can mean “at least one.” The term “circuit” is defined as an integrated circuit (IC) with a plurality of electric elements, such as capacitors, resistors, amplifiers, and the like.

Certain terms used in this specification have predetermined meanings to the inventors. In particular, as used in the disclosure:

“micro LED” refers to a light emitting diode (LED) having a length of approximately 1 μm to 100 μm, and more specifically to an LED having a length of less than or equal to 100 μm;

“photodiode” refers to a photoelectric sensor that converts light into electrical signals;

“forward bias state” refers to a potential of the first anode being greater than a potential of the first cathode;

“negative bias state” refers to a potential of the second cathode being greater than a potential of the second anode.

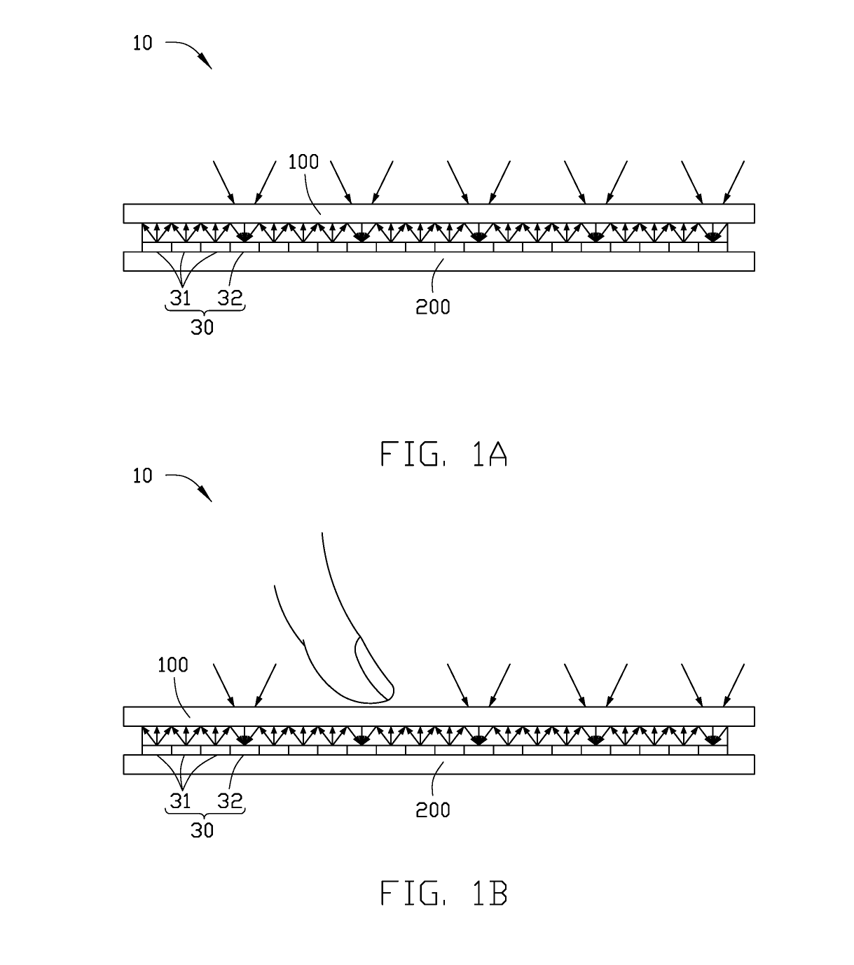

FIG. 1A shows an embodiment of a micro LED touch panel display. In FIG. 1A, the micro LED touch panel display 10 includes a substrate 200. On the substrate 200, there are: a plurality of micro LEDs 31 and a plurality of photodiodes 32. The micro LEDs 31 emit light in a forward bias state, and the photodiodes 32 can detect variations of light intensity caused by fingertip touches, and thus touch positions, in a negative bias state.

Each micro LED 31 includes a first anode 318 and a first cathode 314. Each photodiode 32 includes a second anode 324 and a second cathode 321.

FIG. 1A shows that when no fingertip touches a top surface of the micro LED touch panel display 10, the micro LEDs 31 emit light of different colors to display an image, for example, an image.

FIG. 1B shows a micro LED touch panel display of FIG. 1 when a finger touches the top surface of the micro LED touch panel display 10. The micro LEDs 31 continue emitting light of different colors to display an image. However, because the fingertip is located above the photodiodes 32, the light reaching the photodiodes 32 at the touch position is reduced. Thus, the light intensity reaching the photodiodes 32 at the touch position decreases. A difference in the photo-sensing signals (e.g., photocurrent Iₚₕₒₜₒ) between the corresponding photodiodes 32 at the touch position of the fingertip results. By processing and calculating the difference of the photo-sensing signals (such as photocurrent Iₚₕₒₜₒ), the coordinates of the touch position can be determined. Thus, touch technology is incorporated into the micro LED touch panel display.

In this embodiment, the substrate 200 accommodates the micro LEDs 31 and the photodiodes 32. The micro LED touch panel display 10 further includes a cover, such as cover glass 100, on a side of the micro LEDs 31 and the photodiodes 32 away from the substrate 200 and accessible for a user to touch. The cover glass 100 protects the substrate 200 and the micro LEDs 31 and the photodiodes 32 on the substrate 200. In this embodiment, the micro LED touch panel display 10 does not require any additional layers of touch electrodes. Thus, the overall thickness of the micro LED touch panel display 10 is reduced.

In FIG. 1A and FIG. 1B, the micro LED touch panel display 10 defines a plurality of pixel units 30. Each pixel unit 30 includes at least three micro LEDs 31 emitting light of different colors and also includes one photodiode 32. In other embodiments, the pixel units 30 and the photodiodes 32 may be arranged in a configuration other than the three-to-one configuration, and other suitable configurations may be selected according to actual display quality needs.

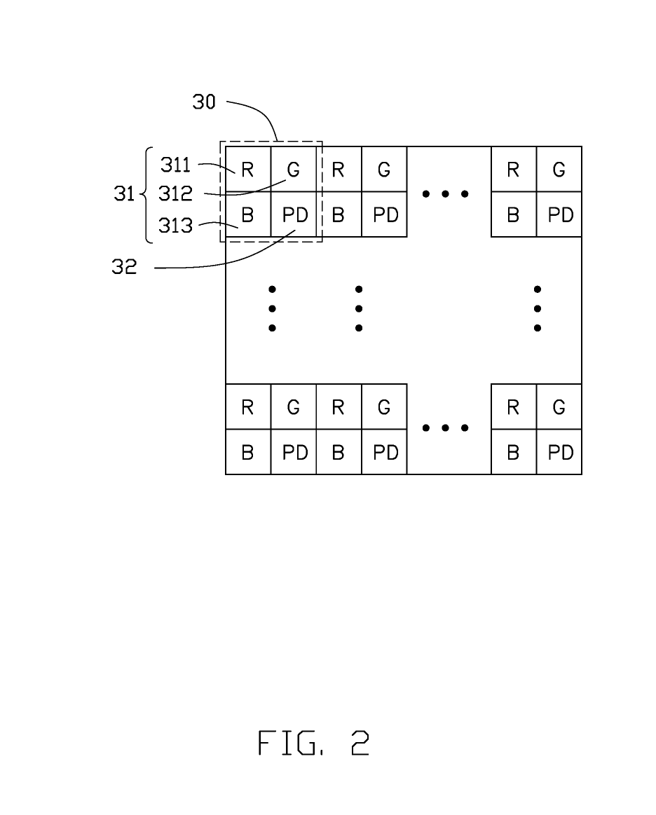

FIG. 2 shows a layout of the pixel units 30 of a micro LED touch panel display. In FIG. 2, the pixel units 30 are arranged in a matrix. Each pixel unit 30 includes a red-light emitting micro LED 311, a green-light emitting micro LED 312, a blue-light emitting micro LED 313, and a photodiode 32. The red-light emitting LED 311, the green-light emitting LED 312, the blue-light emitting LED 313, and the photodiode 32 in each pixel unit 30 are arranged in a 2×2 matrix. The red-light emitting LED 311 and the green-light emitting LED 312 are arranged in the first row of each pixel unit 30 matrix, and the blue-light emitting LED 313 and the photodiode 32 are arranged in the second row of each pixel unit 30 matrix. The first row of the pixel units 30 includes the red-light emitting LEDs 311 and the green-light emitting LEDs 312. The red-light emitting LEDs 311 and the green-light emitting LEDs 312 are arranged alternately along a column direction. In the row (e.g., horizontal) direction, each red-light emitting LED 311 alternates with one green-light emitting LED 312. The second row of the pixel units 30 includes the blue-light emitting LEDs 313 and the photodiodes 32. The blue-light emitting LEDs 313 and the photodiodes 32 are arranged alternately along a column direction. In the row (e.g., horizontal) direction, each blue-light emitting LED 313 alternates with one photodiode 32.

In other embodiments of the present disclosure, the arrangement of the different light color-emitting micro LEDs 31 and the photodiodes 32 is not limited to that shown in the embodiment of FIG. 2. The arrangement of the micro LEDs and photodiodes can be varied as needed, as long as the arrangement retains the 2×2 matrix. In other embodiments of the present disclosure, each pixel unit 30 may also include micro LEDs 31 that emit light of colors other than just red, green, and blue.

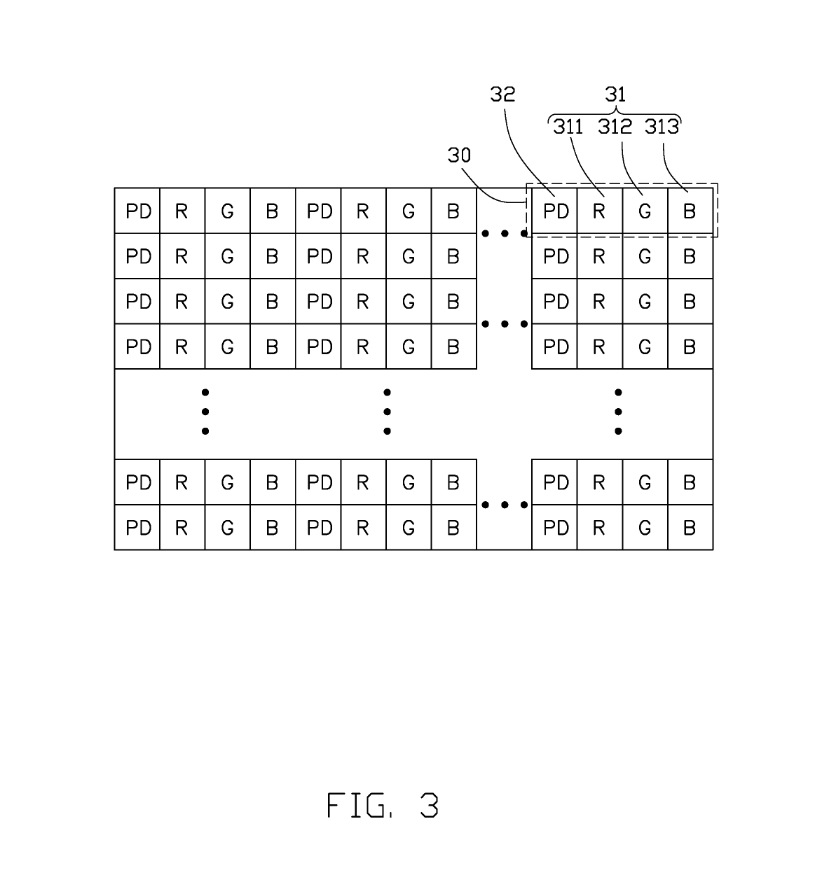

FIG. 3 shows another possible layout of the pixel units of a micro LED touch panel display. In FIG. 3, each pixel unit 30 includes a red-light emitting micro LED 311, a green-light emitting LED 312, a blue-light emitting LED 313, and a photodiode 32. The pixel units 30 are arranged in a matrix. The pixel units 30 in the matrix include columns of photodiodes 32, columns of red-light emitting LEDs 311, columns of green-light emitting LEDs 312, and columns of blue-light emitting LEDs 313. Each matrix column includes: photodiodes 32, red-light emitting LEDs 311, green-light emitting LEDs 312, blue-light emitting LEDs 313. The columns of photodiodes 32, the columns of red-light emitting LEDs 311, the columns of green-light emitting LEDs 312, and the columns of blue-light emitting LEDs 313 are alternatingly arranged along a row direction. In the row direction, each column of photodiodes 32 alternates with one column of red-light emitting LEDs 311, one column of green-light emitting LEDs 312, and one column of blue-light emitting LEDs 313.

In other embodiments of this disclosure, the arrangement of the micro LEDs 31 and the photodiode 32 in each pixel unit 30 is not limited to the embodiment in FIG. 3, and may be adjusted as needed.

In another embodiment, the red-light emitting LED 311, the green-light emitting LED 312, the blue-light emitting LED 313, and the photodiode 322 in each pixel unit 30 may also be arranged in a column direction. The pixel units 30 are arranged in a matrix. The pixel units 30 in the matrix include rows of photodiodes 32, rows of red-light emitting LEDs 311, rows of green-light emitting LEDs 312, and rows of blue-light emitting LEDs 313. Each matrix row includes: photodiodes 32, red-light emitting LEDs 311, green-light emitting LEDs 312, blue-light emitting LEDs 313. The rows of photodiodes 32, the rows of red micro red-light emitting LEDs 311, the rows of green micro green-light emitting LEDs 312 and the rows of blue micro blue-light emitting LEDs 313 are alternatingly arranged along a column direction. In the column direction, each row of photodiodes 32 alternates with one row of red-light emitting LEDs 311, one row of green-light emitting LEDs 312, and one row of blue-light emitting LEDs 313.

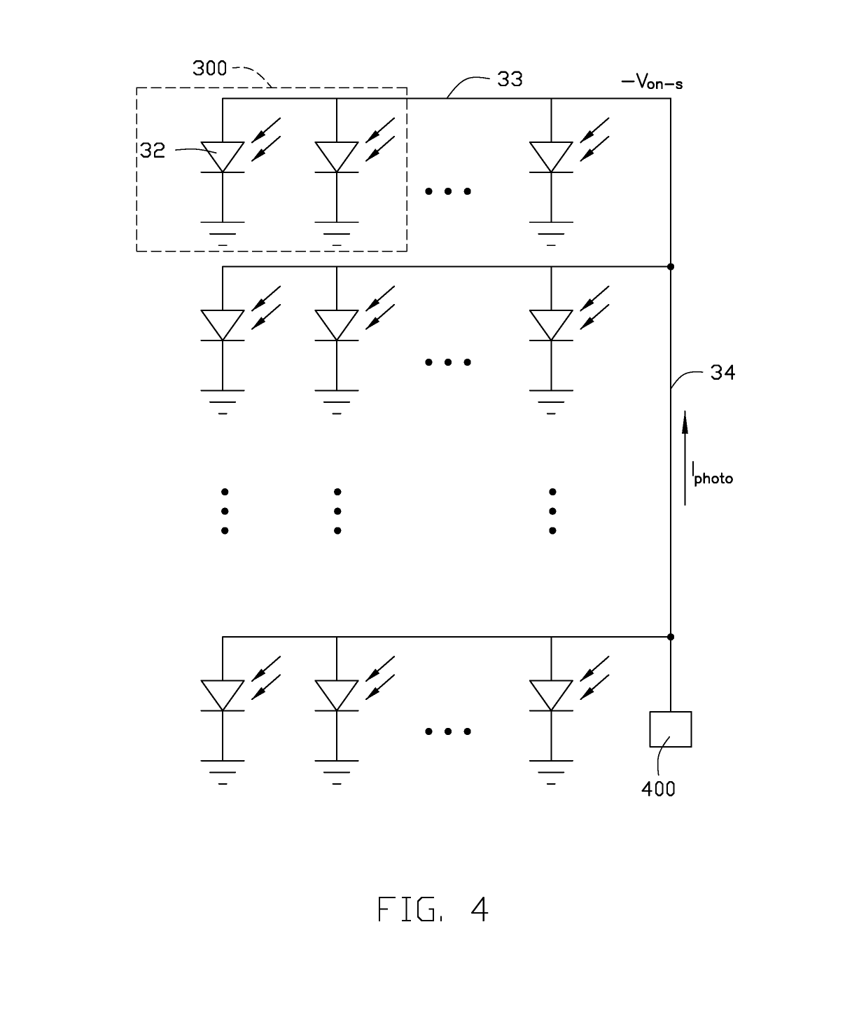

FIG. 4 is a circuit diagram of an embodiment of a touch unit. In FIG. 4, the photodiodes 32 of at least two adjacent pixel units 30 form one touch unit 300, and the photodiodes 32 in each touch unit 300 are arranged in rows and columns. The pixel units 30 corresponding to the photodiodes 32 in each touch unit 300 form a rectangle with a length (i.e., long direction) of about 3 to 5 mm. The second cathode in the touch unit 300 is grounded, and the second anodes in the common, identical row are electrically connected to each other by a first connecting line 33. The second anodes in all the rows are electrically connected to a common, identical voltage supply by a second connecting line 34. Thus, the photodiodes 32 in common, identical touch unit 300 are electrically connected to each other in parallel. In this embodiment, the voltage supply is a negative voltage (−Von-s).

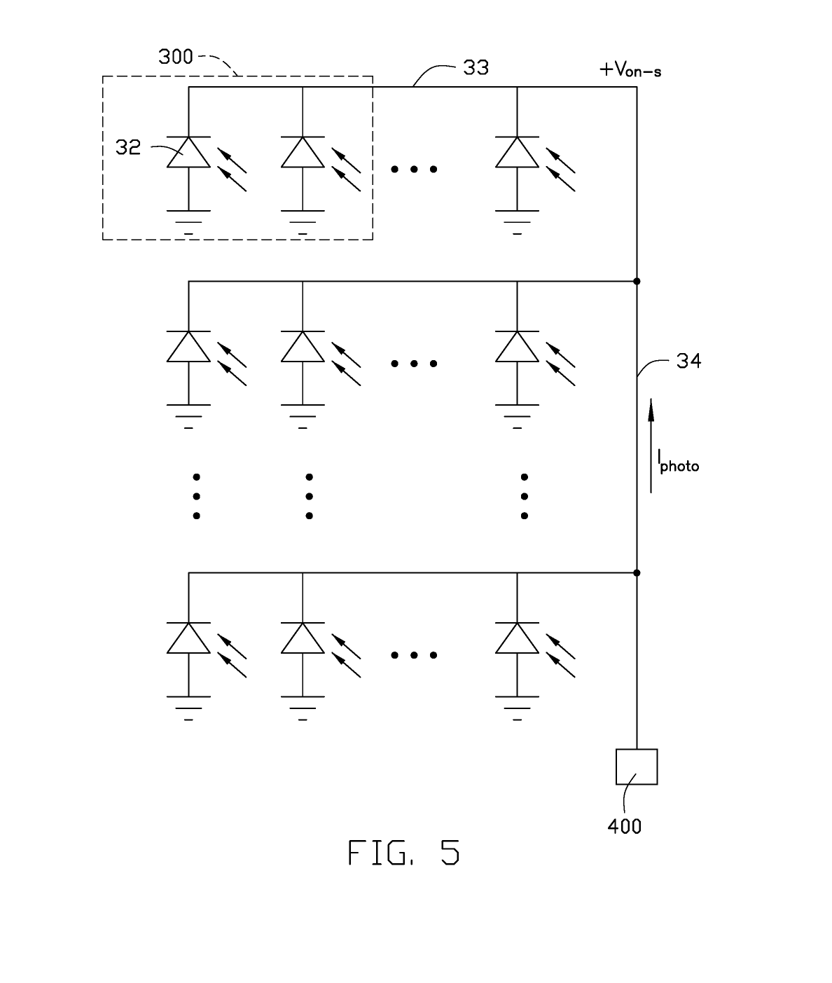

FIG. 5 is a circuit diagram of another embodiment of a touch unit 300. In FIG. 5, the photodiodes 32 of at least two adjacent pixel units 30 form one touch unit 300, and the photodiodes 32 in each touch unit 300 are arranged in rows and columns. In this embodiment, the pixel units 30 and the photodiodes 32 form a rectangle having a length of about 3 to 5 mm. The second anodes in the touch unit 300 are grounded. All the second cathodes of the common, identical row are electrically connected to each other by a first connecting line 33. The second cathodes in each of the different rows are electrically connected to a common, identical voltage by a second connecting line 34. Thus, in a touch display unit touch unit 300, all the photodiodes 32 common, identical are electrically connected in parallel. In this embodiment, the voltage is a positive voltage (+Von-s).

In this embodiment, the micro LED touch panel display 10 further includes a control circuit 400. The control circuit 400 controls whether to supply the voltage and the level of the voltage to the photodiodes 32. The control circuit 400 may be an integrated circuit (IC).

In FIG. 4, the second cathodes in different rows are electrically connected to the control circuit 400 by the second connecting line 34. The control circuit 400 applies a negative voltage to the second anode of each photodiode 32 in the touch unit 300 by the second connecting line 34 and the first connecting lines 33. Thus, the voltage of the second anode in the touch unit 300 is less than the voltage of the second cathode. When light is emitted on any of photodiodes 32, the lit photodiode generates a photo-sensing signal.

In FIG. 5, the second cathodes of a plurality of photodiodes 32 in different rows are electrically connected to the control circuit 400 by the second connecting line 34. The control circuit 400 applies a positive voltage to the second cathode of each photodiode 32 in the touch unit 300 by the second connecting line 34 and the first connecting lines 33. Thus, the potential of the second anode in the touch unit 300 is less than the potential of the second cathode, and each photodiode 32 can generate a photo-sensing signal due to the light intensity above it.

The control circuit 400 receives and processes the photo-sensing signals of the photodiodes 32. In FIG. 4, the photo-sensing signals of the photodiodes 32 in each row of the touch unit 300 are accumulated to the second connecting line 34 by the first connecting lines 33 electrically connected thereto. The photo-sensing signals are received and processed by the control circuit 400 and then the touch position can be relatively and accurately determined.

Similarly, In FIG. 5, the photo-sensing signals of the photodiodes 32 in each row of the touch unit 300 are accumulated to the second connecting line 34 by the first connecting line 33 electrically connected thereto. The photo-sensing signals are received and processed by the control circuit 400, and then the touch position can be relatively and accurately determined.

In this embodiment, when a finger shields light from the photodiodes 32, the photo-sensing signal (such as a photocurrent) varies in the touch area/point. The photo-sensing signal is received by an analog circuit in the control circuit 400, processed by an analog-to-digital converter (ADC), and then the position of the touch area/point is converted by an algorithm.

In this embodiment, the photo-sensing signal read by the control circuit 400 is a sum of the photo-sensing signals of the photodiodes 32 in the touch unit 300, and the sensitivity of the touch point detection is improved by discounting photo-sensing signals having small or difficult to detect values, or changes in value.

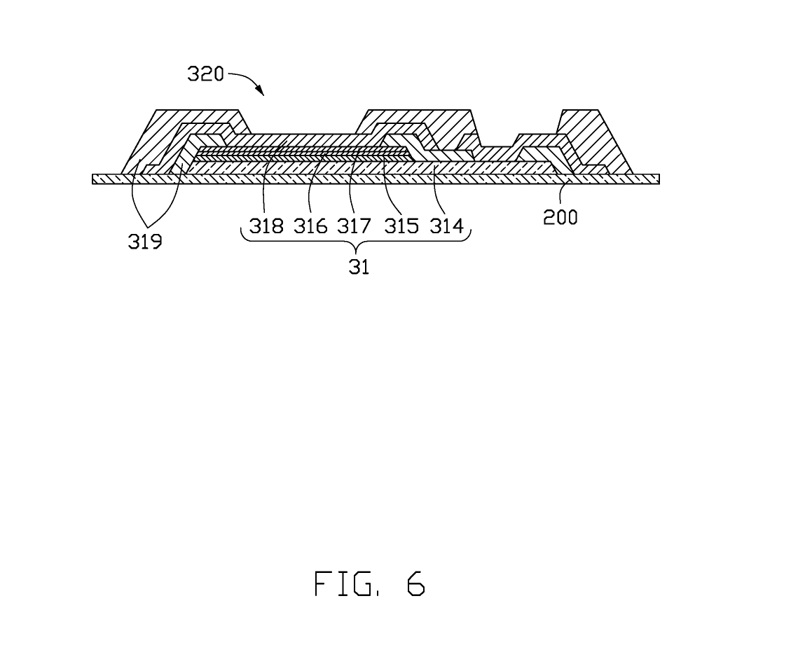

FIG. 6 shows a cross-sectional view of a micro LED. In FIG. 6, the micro LED 31 includes a first cathode layer 314, a first N-type doped phosphor layer 315, a first active layer 316, a first P-doped phosphor layer 317, and a first anode layer 318. A first cathode layer 314 is a transparent conductive layer, and a first cathode layer 314 is electrically connected to the N-type doped phosphor layer 315. The first anode layer 318 is a metal layer and the first anode layer 318 is electrically connected to the p-type doped phosphor layer 317. The first active layer 316 is used to control the color of the light emitted by the micro LED 31.

In FIG. 6, the micro LED touch panel display further includes an insulating layer 319 located on the substrate 200. The insulating layer 319 includes a plurality of via holes 320 penetrating the insulating layer 319. A first cathode layer 314, the N-type doped phosphor layer 315, the first active layer 316, the p-type doped phosphor layer 317, and the first anode layer 318 are located within the via holes 320.

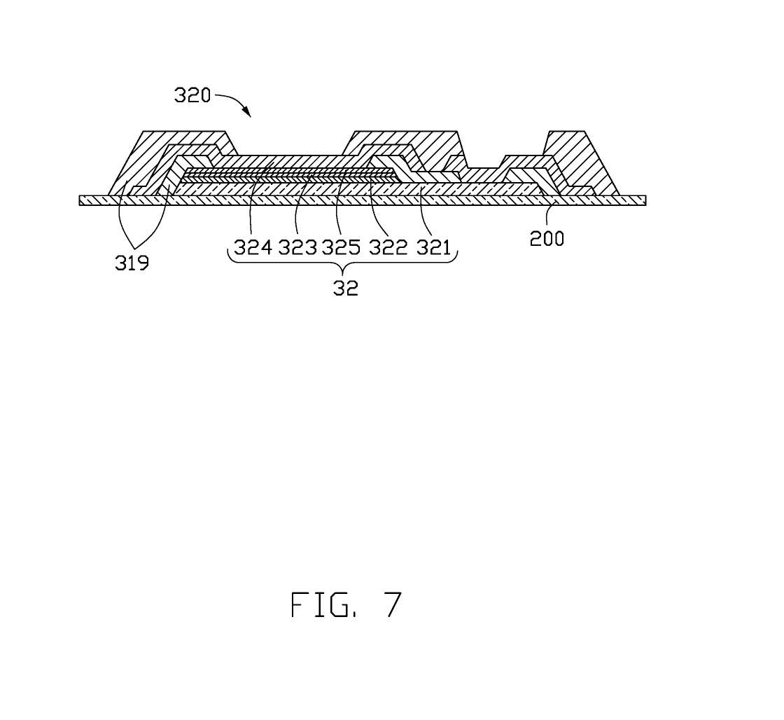

FIG. 7 shows a cross-sectional view of a photodiode. In FIG. 7, the photodiode 32 includes a second cathode layer 321, a second N-doped phosphor layer 322, a second active layer 325, and a second P-doped inorganic phosphor layer 323 and a second anode layer 324. The second cathode layer 321 is a transparent conductive layer, the second cathode layer 321 is electrically connected to the second N-type doped phosphor layer 322 and the second anode layer 324 is a metal layer. The second anode layer 324 is electrically connected to the second P-type doped phosphor layer 323. The second active layer 325 is used to control the photoelectric properties of the photodiode 32.

In FIG. 7, the second cathode layer 321, the second N-type doped phosphor layer 322, the second P-type doped phosphor layer 323, and the second active layer 325 and the second anode layer 324 are located within the via holes 320.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A micro LED touch panel display, comprising:
a plurality of micro LEDs, wherein each micro LED comprises a first anode and a first cathode, each micro LED emits light when a voltage of the first anode is greater than a voltage of the first cathode; and
a plurality of photodiodes, wherein each photodiode comprises a second anode and a second cathode, each anode and cathode having a voltage depending on variations in the light intensity received from the micro LEDS by the photodiode; a touch position is detected when the photodiodes detects a voltage of the second anode of the photodiode is less than a voltage of the second cathode of the photodiode.

2. The micro LED touch panel display of claim 1, wherein the micro LED touch panel display defines a plurality of pixel units, each pixel unit comprises a photodiode and at least three micro LEDs, each micro LED emitting light of a different color.

3. The micro LED touch panel display of claim 2, wherein each pixel unit comprises one red-light emitting LED emitting red light, one green-light emitting LED emitting green light, and one blue-light emitting LED emitting blue light.

4. The micro LED touch panel display of claim 3, wherein the red-light emitting LED, the green-light emitting LED, the blue-light emitting LED, and the photodiode in each pixel unit are arranged in a 2×2 matrix.

5. The micro LED touch panel display of claim 3, wherein the red-light emitting LED, the green-light emitting LED, the blue-light emitting LED, and the photodiode in each pixel unit are arranged in a row.

6. The micro LED touch panel display of claim 2, wherein the photodiodes form a plurality of touch units, each touch unit comprises at least two adjacent photodiodes.

7. The micro LED touch panel display of claim 6, wherein the second cathode of the at least two adjacent photodiodes in each touch unit is grounded, and the second anode of each touch unit is electrically connected to one common, identical negative voltage.

8. The micro LED touch panel display of claim 7 further comprising a control circuit; wherein the second anode of each touch unit is electrically connected to the control circuit, and the common, identical negative voltage is generated by the control circuit.

9. The micro LED touch panel display of claim 8, wherein the touch units are arranged in a matrix, the second anodes of photodiodes aligned in one same row in each touch unit are electrically connected to each other by a first connecting line, and the second anodes of photodiodes aligned in different rows in each touch unit are electrically connected to the control circuit by a second connecting line.

10. The micro LED touch panel display of claim 6, wherein the second anode of each touch unit is grounded, and the second cathode of each touch unit is electrically connected to a common, identical positive voltage.

11. The micro LED touch panel display of claim 9 further comprising a control circuit; wherein the second cathode of each touch unit is electrically connected to the control circuit, and the common, identical positive voltage is generated by the control circuit.

12. The micro LED touch panel display of claim 10, wherein the touch units are arranged in a matrix, the second cathodes of photodiodes aligned in one same row in each touch unit are electrically connected to each other by a first connecting line, and the second cathodes of photodiodes aligned in different rows in each touch unit are electrically connected to the control circuit by a second connecting line.
